(19) United States
(12) Patent Application Publication
(10) Pub. No.: US 2025/0197993 A1
(43) Pub. Date: Jun. 19, 2025

(54) VACUUMING STSTEM, SEMICONDUCTOR PROCESS DEVICE AND VACUUMING METHOD THEREOF

(71) Applicant: BEIJING NAURA MICROELECTRONICS EQUIPMENT CO., LTD., Beijing (CN)

(72) Inventors: Xiaobin SONG, Beijing (CN); Zhen SHEN, Beijing (CN); Zhishun YAN, Beijing (CN)

(21) Appl. No.: 18/846,849

(22) PCT Filed: Mar. 21, 2023
(86) PCT No.: PCT/CN2023/082697

§ 371 Date: Sep. 13, 2024

(30) Foreign Application Priority Data
Mar. 29, 2022 (CN) 202210316224.8

(51) Int. Cl. C23C 16/44; C23C 16/50; H01L 21/67

(52) U.S. Cl. CPC C23C 16/4408; C23C 16/4412; C23C 16/50; H01L 21/67017

(57) ABSTRACT

A vacuuming system includes: multiple first vacuum pumping components and a second vacuum pumping component. The multiple first vacuum pumping components are connected to the multiple process chamber groups in a one-to-one correspondence. Each first vacuum pumping component includes a first vacuum pump and multiple first vacuum pumping pipelines. Outlet ends of the multiple first vacuum pumping pipelines in each first vacuum pumping component are connected to the first vacuum pump. Inlet ends of the multiple first vacuum pumping pipelines in each first vacuum pumping component are respectively connected one-to-one with the multiple process chambers in each process chamber group. The second vacuum pumping component includes a second vacuum pump and a second vacuum pumping pipeline. An outlet end of the second vacuum pumping pipeline is connected to the second vacuum pump. An inlet end of the second vacuum pumping pipeline is connected to all the process chambers respectively.

### TECHNICAL FIELD

The present disclosure relates to the technical field of semiconductor process technologies and, more particularly, to a vacuuming system, a semiconductor process device, and a method for vacuuming a semiconductor process device.

### BACKGROUND

A plasma enhanced chemical vapor deposition (PECVD) device often uses high-frequency electric fields to excite process gases in a high-vacuum quartz chamber to decompose process gases SiH4 and NH3, thereby depositing Si3N4 thin films on surfaces of samples. The PECVD device is highly automated and can meet the needs of solar cell production lines. In a tubular PECVD device, a vacuuming system is a key component. However, a current tubular PECVD device often includes a combination of multiple devices, each of which includes a vacuum pump. Such configuration leads to problems such as occupying a large floor space, consuming too much energy, and costing too much operating multiple vacuum pumps.

### SUMMARY

The purpose of the embodiments of the present disclosure is to provide a vacuuming system, a semiconductor process device, and a method for vacuuming the semiconductor process device, which can at least solve the problem that the tubular PECVD device includes multiple vacuum pumps, resulting in a large occupied area.

To solve the above technical problem, the present disclosure is implemented as follows.

One aspect of the present disclosure provides a vacuuming system for vacuuming multiple process chambers of a semiconductor process device. The vacuuming system includes: multiple first vacuum pumping components, and a second vacuum pumping component. The multiple process chambers are divided into multiple process chamber groups. Each process chamber group includes multiple process chambers. The multiple first vacuum pumping components are connected to the multiple process chamber groups in a one-to-one correspondence. Each first vacuum pumping component includes a first vacuum pump and multiple first vacuum pumping pipelines. Outlet ends of the multiple first vacuum pumping pipelines in each first vacuum pumping component are connected to the first vacuum pump. Inlet ends of the multiple first vacuum pumping pipelines in each first vacuum pumping component are respectively connected one-to-one with the multiple process chambers in each process chamber group. The second vacuum pumping component includes a second vacuum pump and a second vacuum pumping pipeline. An outlet end of the second vacuum pumping pipeline is connected to the second vacuum pump. An inlet end of the second vacuum pumping pipeline is connected to all the process chambers respectively.

Another aspect of the present disclosure provides a semiconductor process device, comprising the disclosed vacuuming system.

Another aspect of the present disclosure provides a method for vacuuming a semiconductor process device, applied to the disclosed vacuuming system. The method includes: in response to a process chamber in a process chamber group undergoing a process, opening multiple first vacuum pipelines in a corresponding vacuum pumping component to use a first vacuum pump to vacuum multiple process chambers connected to the multiple first vacuum pipelines one by one; and in response to a process chamber in the process chamber group having an abnormal alarm during the process, and other process chambers in the process chamber group processing normally, closing the first vacuum pipeline connected to the process chamber with the abnormal alarm, and opening a second vacuum pipeline to use a second vacuum pump to vacuum the process chamber with the abnormal alarm.

In the embodiments of the present disclosure, the multiple process chamber groups can be vacuumed respectively by the multiple first vacuum pumping components. Each first vacuum pumping component includes the first vacuum pump and the multiple first vacuum pumping pipelines. The multiple first vacuum pumping pipelines in each first vacuum pumping component share the first vacuum pump. The inlets of the multiple first vacuum pumping pipelines in each first vacuum pumping component are connected one-to-one with the multiple process chambers in a process chamber group. In this way, the multiple process chambers in each process chamber group can be vacuumed by the first vacuum pump in each first vacuum pumping component. Compared with the method in which each process chamber corresponds to a vacuum pump, the embodiments of the present disclosure can reduce the number of first vacuum pumps included in the vacuuming system, thereby reducing the floor space occupied by the multiple first vacuum pumps, improving the utilization rate of the first vacuum pumps, and further reducing energy consumption and operation costs.

In addition, the second vacuum pumping component includes the second vacuum pump and the second vacuum pumping pipeline. The second vacuum pump is respectively connected to the multiple process chambers through the second vacuum pumping pipeline, to ensure that an alarm is triggered in the abnormal process chamber in each process chamber group. When other process chambers in the same process chamber group are carrying out the process normally, the abnormal process chamber can be vacuumed through the second vacuum pumping pipeline and the second vacuum pump to prevent the abnormal process chamber from sharing the rear-end pipeline with other process chambers that are undergoing the intake process, and being connected to the first vacuum pump together, thereby affecting the process environment of the process chambers of the normal process. By vacuuming the abnormal process chamber through the second vacuum pumping pipeline and the second vacuum pump, it can be avoided that the abnormal process chamber needs to wait until the normal process chamber completes the process before being vacuumed at the same time, thereby reducing wait time, increasing the flexibility of the device, improving the production efficiency, and reducing the production capacity loss caused by process abnormalities.

### BRIEF DESCRIPTION OF THE DRAWINGS

FIG. 1 is a schematic diagram of a layout of a process chamber and a vacuum pump in a PECVD device in the related art;

FIG. 2 is a schematic diagram of connection between a vacuum pumping system and multiple process chambers according to some embodiments of the present disclosure;

FIG. 3 is a schematic diagram of connection between a first vacuum pumping component, a second vacuum pumping component, and a process chamber according to some embodiments of the present disclosure;

FIG. 4 is a schematic diagram of a layout of each group of the first vacuum pumping component and the second vacuum pumping component, and a corresponding process chamber according to some embodiments of the present disclosure;

FIG. 5 is a schematic diagram of a control valve in a first state according to some embodiments of the present disclosure; and

FIG. 6 is a schematic diagram of a control valve in a second state according to some embodiments of the present disclosure.

### DETAILED DESCRIPTION OF THE EMBODIMENTS

The following will clearly and completely describe the technical solutions in the embodiments of the present disclosure with reference to the accompanying drawings. Obviously, the described embodiments are merely part of the embodiments of the present disclosure, not all of the embodiments. Based on the embodiments in the present disclosure, all other embodiments obtained by ordinary technicians in the field without creative work are within the scope of the present disclosure.

The terms “first”, “second”, etc. in the specification and claims of the present disclosure are used to distinguish similar objects, not to describe a specific order or sequence. It should be understood that the data used in this way can be interchanged where appropriate, such that the embodiments of the present disclosure can be implemented in an order other than those illustrated or described herein, and the objects distinguished by “first”, “second”, etc. are usually of one type, and the number of objects is not limited. For example, the first object can be one or more. In addition, “and/or” in the specification and claims refers to at least one of connected objects, and the character “/” generally refers to that the objects associated with each other are in an “or” relationship.

The following is a detailed description of the embodiments of the present disclosure through specific embodiments and their application scenarios in combination with the drawings.

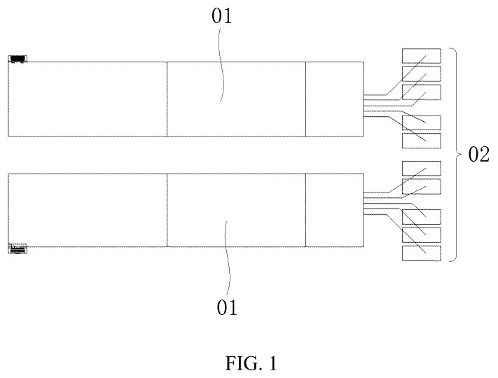

FIG. 1 is a schematic diagram of a layout of a process chamber and a vacuum pump in a PECVD device. Referring to FIG. 1, the related art provides a ten-tube solar cell production device, which includes two five-tube solar cell production devices, and the two five-tube solar cell production devices are placed in a factory. The ten-tube solar cell production device includes ten quartz chambers 01 and ten vacuum pumping systems. Each vacuum pumping system includes a vacuum pump 02, such that the vacuum pump 02 corresponds to the quartz chamber 01 one by one. Each vacuum pump 02 vacuums the corresponding quartz chamber 01. A vacuum pumping process is independently performed on each quartz chamber 01 without interfering with each other.

When arranging ten vacuuming systems, a certain safety distance and maintenance space must be kept between the vacuum pumps 02 of each of two adjacent vacuuming systems to facilitate secondary piping and subsequent maintenance. As a result, the vacuum pumps 02 of each of the ten vacuuming systems occupy a large area, resulting in part of the area of the factory being wasted. Moreover, a process time of each tube is relatively short. For example, the process time is 43 minutes, and a deposition process time is about 20 minutes, which only accounts for 46% of the process time. Excluding processes that do not require operation of the vacuum pump 02, such as entering and exiting of a wafer carrying boat, and heating, the remaining time of about 23 minutes is an idle time of the vacuum pump 02. In this way, an actual utilization rate of the vacuum pump 02 is relatively low, and the vacuum pump 02 is idle most of the time, resulting in a waste of resources.

Based on the above situation, the present disclosure provides a new vacuum pumping system, which can reduce a floor space occupied by a vacuum pump to reduce resource waste.

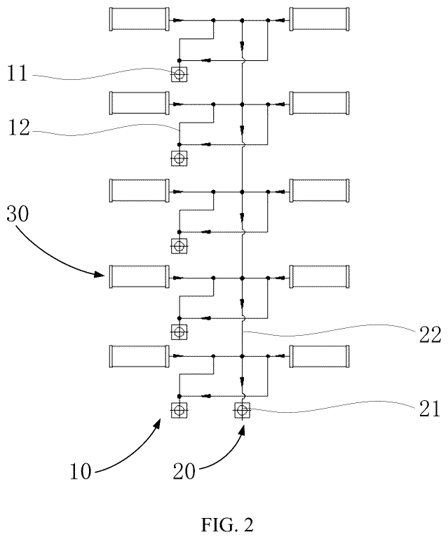

Referring to FIGS. 2 to 6, the present disclosure provides a vacuum pumping system, which is applied to a semiconductor process device. The semiconductor process device includes multiple process chambers 30. The multiple process chambers 30 of the semiconductor process device may be vacuumed by the vacuum pumping system. The multiple process chambers 30 may be divided into multiple process chamber groups, and each process chamber group includes multiple process chambers 30.

In some embodiments, the vacuum pumping system includes ten process chambers 30, divided into five process chamber groups, two process chambers in each process chamber group, and the two process chambers 30 in each process chamber group are arranged back-to-back. Of course, the present disclosure does not impose specific restrictions on the number of process chambers 30 and the arrangement thereof. For example, the vacuum pumping system may include 9 process chambers 30, divided into three process chamber groups, three process chambers in each process chamber group. In another example, the vacuum pumping system may include 16 process chambers 30, divided into four process chamber groups, four process chambers in each process chamber group, and so on.

In some embodiments, the vacuum pumping system includes multiple first vacuum pumping components 10 and a second vacuum pumping components 20. The multiple first vacuum pumping components 10 are connected one-to-one with the multiple process chamber groups, to vacuum the multiple process chamber groups respectively through the multiple first vacuum pumping components 10. In addition, the second vacuum pumping component 20 may also be used to vacuum the process chambers 30.

Each first vacuum pumping component 10 includes a first vacuum pump 11 and multiple first vacuum pumping pipelines 12. Outlet ends of the multiple first vacuum pumping pipelines 12 in each first vacuum pumping component 10 are connected to the first vacuum pump 11, and inlet ends of the multiple first vacuum pumping pipelines 12 in each first vacuum pumping component 10 are respectively connected one-to-one with the multiple process chambers 30 in each process chamber group.

Specifically, gas outlets of the multiple first vacuum pumping pipelines 12 in each first vacuum pumping component 10 are connected to a gas inlet of the first vacuum pump 11, and gas inlets of the multiple first vacuum pumping pipelines 12 are connected to gas outlets at tails of the multiple process chambers 30 in the process chamber group in a one-to-one correspondence. In this way, when the first vacuum pump 11 in each first vacuum pumping component 10 is started, gases in the multiple process chambers 30 in the process chamber group may be extracted through the multiple first vacuum pumping pipelines 12, such that residual process gases in the process chambers 30 can be removed to facilitate subsequent processes.

In some embodiments, each first vacuum pumping component 10 may include one first vacuum pump 11 and two first vacuum pumping pipelines 12, and accordingly, each process chamber group includes two process chambers 30. At this time, the gas inlets of the two vacuum pumping pipelines 12 are connected to the gas outlets of the two process chambers 30 respectively, to vacuum the two process chambers 30 respectively.

In some embodiments, the multiple first vacuum pumping pipelines 12 in each first vacuum pumping component 10 share one first vacuum pump 11, such that the multiple process chambers 30 in the process chamber group can be vacuumed respectively through the shared first vacuum pump 11. It should be noted here that one of the process chambers 30 in each process chamber group can be vacuumed first by controlling on and off of one of the first vacuum pumping pipelines 12, and then the other process chambers 30 can be vacuumed. Of course, the multiple first vacuum pumping pipelines 12 in each first vacuum pumping component 10 can also be controlled to be connected at the same time to vacuum the multiple process chambers 30 in each process chamber group at the same time. The specific situation can be selected according to the actual operation conditions.

In some embodiments, the second vacuum pumping component 20 includes a second vacuum pump 21 and a second vacuum pumping pipeline 22. An outlet end of the second vacuum pumping pipeline 22 is connected to the second vacuum pump 21, and an inlet end of the second vacuum pumping pipeline 22 is connected to the multiple process chambers 30 (i.e., all process chambers 30) respectively.

Specifically, a gas outlet of the second vacuum pumping pipeline 22 is connected to a gas inlet of the second vacuum pump 21, and a gas inlet of the second vacuum pumping pipeline 22 is connected to the gas outlets at the tails of the multiple process chambers 30. In this way, when the second vacuum pump 21 is started, the gas in any process chamber 30 can be extracted through the second vacuum pumping pipeline 22, thereby improving the flexibility of a vacuum pumping process and ensuring process requirements.

It should be noted here that in order to connect the second vacuum pumping pipeline 22 to the multiple process chambers 30 respectively, multiple branch pipes (such as the branch pipes 221 described below) can be configured at the inlet end of the second vacuum pumping pipeline 22, and each branch pipe is connected to a corresponding process chamber 30. In addition, to vacuum one or more process chambers 30 in a targeted manner, a switch valve (such as a fourth switch valve 222 described below) can be configured on each branch pipe to control the connection or disconnection of the branch pipe, such that some of the multiple process chambers 30 can be vacuumed according to actual conditions.

In some embodiments, multiple first vacuum pumping components 10 can be used to vacuum multiple process chamber groups, and each first vacuum pumping component 10 can vacuum the multiple process chambers 30 in each process chamber group separately or simultaneously. Each first vacuum pumping component 10 includes one first vacuum pump 11. The multiple process chambers 30 in each process chamber group may be vacuumed by one first vacuum pump 11, that is, a one-to-many mode is adopted. The number of first vacuum pumps 11 used can be reduced compared to a mode in which each process chamber 30 corresponds to one first vacuum pump 11. In this way, the floor space occupied by the multiple first vacuum pumps 11 can be reduced, the utilization rate of the first vacuum pumps 11 can be improved, and energy consumption and operating costs can be reduced.

In addition, the second vacuum pumping component 20 includes the second vacuum pump 21 and the second vacuum pumping line 22, and the second vacuum pump 21 is connected to the multiple process chambers 30 respectively through the second vacuum pumping line 22, such that the multiple process chambers 30 can be vacuumed by the second vacuum pump 21. As such, abnormal process chambers 30 may be prevented from having to wait for normal process chambers 30 to complete the process before vacuuming at the same time, thereby reducing wait time, increasing the flexibility of the process device, improving production efficiency, and reducing production capacity loss caused by process abnormalities.

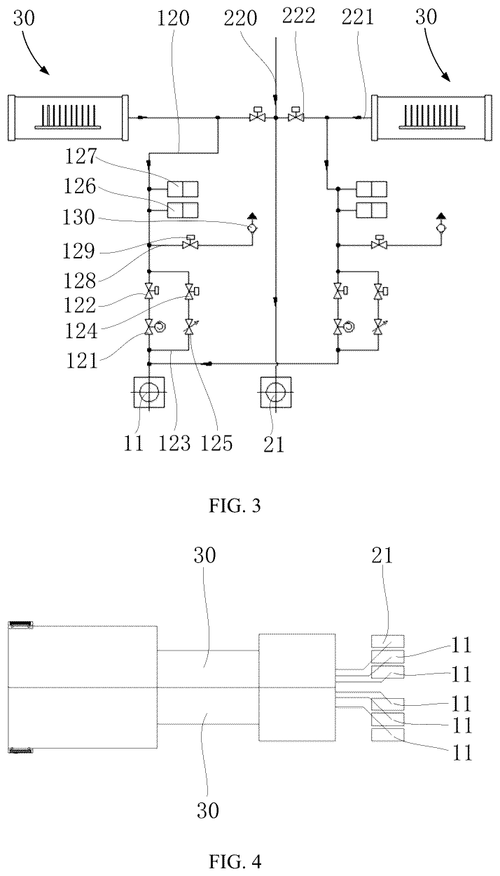

In some embodiments, as shown in FIG. 3, the first vacuum pumping pipeline 12 may include a main pipeline 120, a control valve 121, and a first switch valve 122. The main pipeline 120 is used to connect the first vacuum pump 11 and the process chamber 30, and the control valve 121 and the first switch valve 122 are both arranged in the main pipeline 120. In some embodiments, the control valve 121 is located between the first switch valve 122 and the first vacuum pump 11. In some other embodiments, the control valve 121 may also be exchanged with the first switch valve 122.

The main pipeline 120 is used to circulate gases. A gas inlet of the main pipeline 120 is connected to the gas outlet at the tail of the process chamber 30, and a gas outlet of the main pipeline 120 is connected to the gas inlet of the first vacuum pump 11. In this way, under the action of the first vacuum pump 11, the gas in the process chamber 30 may flow along the main pipeline 120 toward the first vacuum pump 11, such that the residual process gas in the process chamber 30 can be discharged.

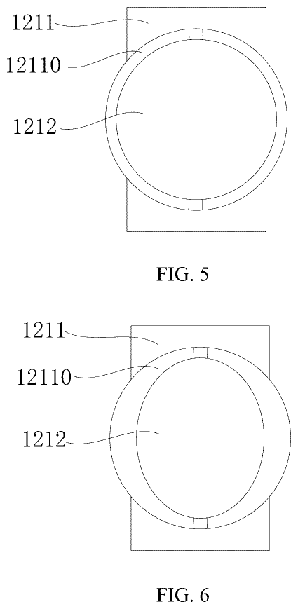

The control valve 121 is used to control the flow of the gases in the main pipeline 120 to control an operation pressure in the main pipeline 120. In some embodiments, as shown in FIG. 5, the control valve 121 may include a valve body 1211 and a valve plate 1212, and the valve plate 1212 is rotatably arranged in the valve body 1211 through a rotating shaft. The rotating shaft may be connected to a driving component, or a rotating handle is provided on the rotating shaft. In this way, a driving force is introduced through the rotating shaft to drive the valve plate 1212 to rotate in the valve body 1211, such that a gap between an edge of the valve plate 1212 and an inner wall of the valve body 1211 can be changed. That is, an opening of the control valve 121 is changed by rotating the valve plate 1212, thereby achieving the control of a gas flow in the main pipeline 120 to adjust a vacuum speed. In some embodiments, the control valve 121 may be a butterfly valve, but is not limited thereto, and may also be in other forms.

The first switch valve 122 is used to control the connection or disconnection of the main pipeline 120. Specifically, when it is necessary to vacuum the process chamber 30, the first switch valve 122 is switched to an open state, and the vacuum operation may be performed at this time. When it is not necessary to vacuum the process chamber 30, to prevent a gas leak and cause the process chamber 30 to fail to reach a preset vacuum level, the first switch valve 122 may be switched to a closed state, such that the main pipeline 120 can be disconnected to avoid the gas leak. In some embodiments, the first switch valve 122 may be a stop valve, but is not limited thereto, and may also be in other forms.

Based on the above configurations, by using the control valve 121 and the first switch valve 122 in conjunction, it is possible to control the on and off of the main pipeline 120 and control the gas flow in the main pipeline 120, such that vacuuming can be performed according to process requirements.

In some other embodiments, the first vacuum pumping pipeline 12 may include the main pipeline 120 and the first switch valve 122. The main pipeline 120 connects the first vacuum pump 11 and the process chamber 30. The first switch valve 122 is arranged in the main pipeline 120. Based on this, the opening and closing of the first switch valve 122 may control the connection or disconnection of the main pipeline 120 to meet the process requirements. In some embodiments, the first switch valve 122 may be a stop valve, but is not limited thereto, and may also be in other forms.

In some embodiments, the first vacuum pumping pipeline 12 may further include a bypass line 123. An inlet end of the bypass line 123 is connected to the main line 120. The connection is located upstream of the first switch valve 122 and the control valve 121. That is, when the first switch valve 122 is located upstream of the control valve 121, the connection between the inlet end of the bypass line 123 and the main line 120 is located between the first switch valve 122 and the process chamber 30. When the control valve 121 is located upstream of the first switch valve 122, the connection between the inlet end of the bypass line 123 and the main line 120 is located between the control valve 121 and the process chamber 30. An outlet end of the bypass pipe 123 is connected to the main pipe 120, and the connection is located downstream of the first switch valve 122 and the control valve 121. That is, when the control valve 121 is located downstream of the first switch valve 122, the connection between the outlet end of the bypass pipe 123 and the main pipe 120 is located between the control valve 121 and the first vacuum pump 11. When the first switch valve 122 is located downstream of the control valve 121, the connection between the outlet end of the bypass pipe 123 and the main pipe 120 is located between the first switch valve 122 and the first vacuum pump 11. In addition, a nominal diameter of the bypass pipe 123 is smaller than a nominal diameter of the main pipe 120, and the bypass pipe 123 is provided with a second switch valve 124. Based on this, the second switch valve 124 may be arranged in parallel with the first switch valve 122 and the control valve 121 respectively. It should be understood that the nominal diameter is a common diameter of each pipeline. It should be noted here that the upstream in the present disclosure specifically refers to a front side along a gas flow direction during the vacuuming process, and the downstream refers to a rear side along the gas flow direction during the vacuuming process.

The second switch valve 124 is used to control the connection or disconnection of the bypass pipe 123. When it is necessary to vacuum through the bypass pipe 123, the second switch valve 124 may be switched to the open state to connect the bypass pipe 123, such that the gas in the process chamber 30 can flow along the bypass pipe 123 to the first vacuum pump 11 to achieve vacuuming. When it is not necessary to vacuum through the bypass pipe 123, the second switch valve 124 may be switched to the closed state to disconnect the bypass pipe 123, such that the gas in the process chamber 30 cannot flow along the bypass pipe 123 to the first vacuum pump 11. In some embodiments, the second switch valve 124 may be a pneumatic stop valve.

Based on the above configurations, because the nominal diameter of the bypass pipeline 123 is smaller than the nominal diameter of the main pipeline 120, a flow conductance of the bypass pipeline 123 is smaller, and thus, a pumping speed of vacuuming can be adjusted by switching the bypass pipeline 123 on and off. Specifically, in an initial stage of vacuuming the process chamber 30, the first switch valve 122 is closed and the second switch valve 124 is opened. At this time, under a suction action of the first vacuum pump 11, the gas in the process chamber 30 first flows along a section of the main pipeline 120 between the first switch valve 122 and the process chamber 30, and then enters the bypass pipeline 123 and continues to flow along the bypass pipeline 123, and then enters a section of the main pipeline 120 between the control valve 121 and the first vacuum pump 11 from the bypass pipeline 123, and flows along the main pipeline 120, and is finally discharged by the first vacuum pump 11, thereby achieving a pre-vacuuming process of the process chamber 30.

During the pre-vacuuming process, because the conductance of the bypass pipe 123 is relatively small, a pumping speed of the gas in the process chamber 30 by the first vacuum pump 11 is limited, thereby alleviating vibration of the wafer on a graphite boat (i.e., wafer carrying boat), preventing the wafer from being scratched, and reducing a wafer fragmentation rate.

After a period of time in the pre-vacuuming process, the first switch valve 122 is opened and the second switch valve 124 is closed. At this time, the main pipeline 120 is completely unblocked, and the bypass pipeline 123 is disconnected, such that the gas in the process chamber 30 flows along the main pipeline 120 and is finally discharged by the first vacuum pump 11, thereby achieving the vacuuming of the process chamber 30 to quickly extract the residual process gas.

It should be noted here that in the embodiment of the present disclosure, by configuring the bypass pipeline 123 for pre-vacuuming, the pumping speed of the entire vacuuming process in the initial stage can be reduced. Compared with the method of using a larger pumping speed in the entire vacuuming process, the vacuuming process in the embodiment of the present disclosure is unlikely to damage the wafer in the initial stage of vacuuming, ensuring the yield of wafers.

To further adjust the flow conductance of the bypass pipeline 123, a regulating valve 125 may also be configured in the bypass pipeline 123. In some embodiments, the regulating valve 125 is located downstream of the second switch valve 124, that is, between the outlet end of the bypass pipeline 123 and the second switch valve 124. In some other embodiments, the regulating valve 125 may also be exchanged with the second switch valve 124. As such, a flow cross-sectional area of the bypass pipeline 123 can be adjusted by controlling the opening of the regulating valve 125, thereby adjusting the flow conductance of the bypass pipeline 123, and then achieving a vacuuming process with multiple pumping speeds to improve adaptability of the vacuuming system. In some embodiments, the regulating valve 125 may be a manual regulating valve, but is not limited thereto, and may also be in other forms.

To control the operation pressure in the process chamber 30, the first vacuum pumping pipeline 12 may further include a pressure sensor 127, which is connected to the main pipeline 120. The connection is located upstream of the connection between the inlet end of the bypass pipeline 123 and the main pipeline 120. That is, when the first switch valve 122 is located upstream of the control valve 121, the connection between the pressure sensor 127 and the main pipeline 120 is located upstream of the first switch valve 122. When the control valve 121 is located upstream of the first switch valve 122, the connection between the pressure sensor 127 and the main pipeline 120 is located upstream of the control valve 121, that is, the pressure sensor 127 is located between the inlet end of the bypass pipeline 123 and the connection between the main pipeline 120 and the process chamber 30. As such, a vacuum pressure in the main pipeline 120 can be detected by the pressure sensor 127.

In some embodiments, during the pre-vacuuming process, the first vacuum pump 11 is started, the first switch valve 122 is closed, and the second switch valve 124 is opened. As the first vacuum pump 11 is running, the gas in the process chamber 30 enters the first vacuum pump 11 along a section of the main pipeline 120, the bypass pipeline 123, and another section of the main pipeline 120, and is discharged by the first vacuum pump 11. During this process, the pressure sensor 127 detects the vacuum pressure in the main pipeline 120 in real time. When the vacuum pressure in the main pipeline 120 reaches a preset pressure, that is, when the vacuum pressure in the process chamber 30 reaches the preset pressure, the first switch valve 122 is opened and the second switch valve 124 is closed. At this time, the gas in the process chamber 30 completely enters the first vacuum pump 11 along the main pipeline 120 and is discharged by the first vacuum pump 11. During this process, the opening of the control valve 121 may be adjusted according to a detection result of the pressure sensor 127, to control the operation pressure in the process chamber 30 to meet the process requirements.

After the process is completed, it is necessary to fill the process chamber 30 with nitrogen to achieve pressure relief. To detect the operation pressure in the process chamber 30 after nitrogen filling, the first vacuum line 12 may also include a pressure switch 126, which is connected to the main pipeline 120. The connection is located upstream of the connection between the inlet end of the bypass pipeline 123 and the main pipeline 120, for example, between the pressure sensor 127 and the connection between the inlet end of the bypass pipeline 123 and the main pipeline 120, or the pressure switch 126 may also be exchanged with the pressure sensor 127. The pressure switch 126 is used to detect a gas pressure in the main pipeline 120. As such, when the gas pressure in the main pipeline 120 (or, the process chamber 30) reaches a pressure specified by the pressure switch 126, a furnace door of the process chamber 30 may be opened to facilitate pressure relief. It should be noted here that the specific structure and operation principle of the pressure switch 126 may refer to the relevant technology, which will not be repeated herein.

In some embodiments, after the process is completed, the first switch valve 122 and the second switch valve 124 are both closed, and the main pipeline 120 is disconnected. Then nitrogen may be filled into the process chamber 30 through a nitrogen filling device to achieve nitrogen backfilling, such that the vacuum level in the process chamber 30 gradually decreases and the gas pressure gradually increases. When the pressure reaches a value specified by the pressure switch 126, the furnace door of the process chamber 30 may be opened to achieve pressure relief.

In addition, the first vacuum pumping pipeline 12 may also include a pressure relief pipeline 128, a third switch valve 129, and a one-way valve 130. One end of the pressure relief pipeline 128 is connected to the main pipeline 120, and the connection is located between the inlet end of the bypass pipeline 123 and the connection between the main pipeline 120 and the pressure switch 126. The third switch valve 129 and the one-way valve 130 are both arranged in the pressure relief pipeline 128, and the one-way valve 130 is located downstream of the third switch valve 129.

Based on the above configurations, when the gas pressure in the main pipeline 120 reaches the value defined by the pressure switch 126, the furnace door may be opened, and at the same time, the third switch valve 129 is opened, such that the gas is discharged through the third switch valve 129 and the one-way valve 130 in sequence to present a pressure relief protection state, and can prevent an external gas from entering the main pipeline 120 and the process chamber 30 through the pressure relief pipeline 128.

In some embodiments, the control valve 121 may be the butterfly valve. The control valve 121 may include the valve body 1211 and the valve plate 1212. The valve body 1211 includes a through cavity 12110, and the valve plate 1212 is rotatably arranged in the through cavity 12110 with its radial direction as a rotation axis. When the valve plate 1212 is perpendicular to the rotation axis of the through cavity 12110, a preset gap is formed between the edge of the valve plate 1212 and an inner wall of the through cavity 12110. In some embodiments, the preset gap may range from 0.01 mm to 0.1 mm, including 0.01 mm, 0.03 mm, 0.05 mm, 0.08 mm, 0.1 mm, etc. Of course, it may also be other values, which are not specifically limited in the embodiments of the present disclosure.

Based on the above configurations, the valve plate 1212 and the valve body 1211 may no longer rub against each other. At the same time, due to the existence of the preset gap, even if dust in the process chamber 30 accumulates in the control valve 121, the valve plate 1212 is unlikely stuck. Thus, under the premise of ensuring stability of a process pressure, the control valve 121 may be further guaranteed to operate normally, maintenance time of the control valve 121 is reduced, and service life of the control valve 121 is extended.

To connect the second vacuum pumping pipeline 22 to multiple process chambers 30 respectively, the second vacuum pumping pipeline 22 may include a common pipeline 220, multiple branch pipelines 221, and multiple fourth switch valves 222. Inlet ends of the multiple branch pipes 221 are connected to multiple process chambers 30 (that is, all process chambers 30) one by one, and outlet ends of the multiple branch pipes 221 are all connected to the common pipeline 220. The common pipeline 220 is connected to the second vacuum pump 21. The multiple fourth switch valves 222 are configured one by one in the multiple branch pipelines 221. In this way, the opening or closing of the multiple fourth switch valves 222 can control the opening and closing of the branch pipelines 221 where they are located.

Based on the above configurations, when the second vacuum pump 21 is started, the gas in the common pipeline 220 may be extracted. When it is necessary to extract the gas in one or more process chambers 30, the fourth switch valve 222 on the branch pipeline 221 connected to the process chamber 30 may be opened to achieve vacuuming.

It should be noted here that, in some cases, the first vacuum pump 11 in each first vacuum pumping component 10 is a primary pump, and the second vacuum pump 21 may be a secondary or standby pump. That is, the second vacuum pump 21 may be turned on in special circumstances (such as abnormalities in the process, etc.) for scheduling and emergency problem handling.

During the process, due to abnormalities such as radio frequency alarms, one or more process chambers 30 in the process chamber group corresponding to each first vacuum pumping component 10 may exit the process early. Based on the principle of connected chambers, multiple process chambers 30 in the process chamber group cannot maintain different pressures when sharing the common rear pipeline. When the process in one or more process chambers 30 in the process chamber group terminates (i.e., abnormal alarm) and the process in the remaining process chambers 30 is carried out normally, pressure differences between the process chamber 30 where the process is terminated and the process chambers 30 where the process is carried out normally may be substantial. To prevent the wafers in the process chambers 30 of the normal process from being damaged and to ensure a desired wafer yield, the first vacuum pipeline 12 of the process chamber 30 with the abnormal process is disconnected at this time. The process chamber 30 with the abnormal process needs to wait for the process in the process chamber 30 of the normal process to be completed before vacuuming can be performed at the same time, which substantially degrades production efficiency.

Based on the above situation, the second vacuum pump 21 may be started to solve the above problem. Specifically, when one or more process chambers 30 in each process chamber group give an abnormal alarm during the process, and other process chambers 30 in the same process chamber group are performing the process normally, the process gas may be stopped from entering the process chamber 30 with the abnormal alarm, the first switch valve 122 is closed in the first vacuum pumping pipeline 12 corresponding to the process chamber 30 with abnormal alarm (at this time, the second switch valve 124 is in a closed state), and the fourth switch valve 222 is opened in the branch pipeline 221 connected to the process chamber 30 with the abnormal alarm. At this time, the process chamber 30 with the abnormal alarm is vacuumed by the second vacuum pump 21 through the common pipeline 220 and the corresponding branch pipeline 221 to ensure that the residual process gas in the process chamber 30 with the abnormal alarm is completely extracted.

When the vacuum pressure in the process chamber 30 with the abnormal alarm reaches the preset pressure, the process chamber 30 is backfilled with nitrogen through the nitrogen filling device. When the gas pressure in the process chamber 30 reaches a specified value, the furnace door may be opened and the pressure may be released. After the alarm is processed, the process may resume.

In the above process, the process in other process chambers 30 in the same process chamber group as the process chamber 30 with the abnormal alarm is carried out normally without being affected by the abnormal process.

Based on the above configurations, the requirement that the multiple process chambers 30 in the same process chamber group need to enter and exit at the same time is satisfied, thereby reducing the wait time, increasing the flexibility of the device, and reducing the production capacity loss caused by device or discharge abnormalities.

In addition, to achieve connection and sealing of various valves and pipelines, or various pumps and pipelines, the valves and pipelines may be connected through standard caliper screws and sealing components, thereby ensuring both the reliability of the connection and the tightness of the connection.

For example, a first flange may be configured at an end of a valve, and a second flange may be configured at an end of a pipeline. During installation, the first flange and the second flange are butt-jointed, and a sealing gasket, such as a sealing ring, is disposed between the first flange and the second flange. Two ends of a caliper are respectively placed on the outside of the first flange and the second flange. Screws are tightened to bring the two ends of the caliper close to each other, thereby achieving clamping of the first flange and the second flange. It should be noted here that standard caliper screws can also refer to the existing technology.

In some embodiments, the main pipeline 120 may be connected to the first switch valve 122, the control valve 121, or the first vacuum pump 11 by standard caliper screws and sealing components. The bypass pipeline 123 may be connected to the second switch valve 124 or the regulating valve 125 by standard caliper screws and sealing components. The pressure relief pipeline 128 and the third switch valve 129 may be connected by standard caliper screws and sealing components. The common pipeline 220 and the second vacuum pump 21, and the branch pipeline 221 and the fourth switch valve 222 may also be connected by standard caliper screws and sealing components.

Based on the above vacuum pumping system, the present disclosure also provides a semiconductor process device. The semiconductor process device includes the above vacuum pumping system.

Based on the above semiconductor process device, the present disclosure also provides a method for vacuuming the semiconductor process device, which is applied to the above semiconductor process device. The method includes: when a process chamber in each process chamber group is processing, multiple first vacuum pipelines in the corresponding vacuum pumping component are opened to use a first vacuum pump to vacuum multiple process chambers connected to the multiple first vacuum pipelines one by one; when one or more process chambers in a process chamber group have abnormal alarms during the process, and other process chambers in the same process chamber group are processing normally, the first vacuum pipeline connected to the process chamber with the abnormal alarms is closed, and the second vacuum pipeline is opened at the same time, to use the second vacuum pump to vacuum the process chamber with the abnormal alarms.

It should be noted here that in the embodiments of the present disclosure, the specific implementation process and principle of the method for vacuuming the semiconductor process device have been previously described in detail, and the previous description may be referred to for details, which will not be repeated herein.

The embodiments of the present disclosure reduces the floor space of the vacuuming system, saves energy, reduces costs, and increase the output per unit area. Further, the present disclosure reduces the maintenance time of the control valve 121, extends the service life of the control valve 121, and improves productivity. Further, the present disclosure reduces the scratches and breakage of the wafer, and improves the yield rate of the wafers. In addition, the present disclosure also reduces the wait time when process abnormalities occur, increases the flexibility of the device, and reduces the loss of production capacity.

The embodiments of the present disclosure are described above in conjunction with the accompanying drawings, but the present disclosure is not limited to the above-described specific implementation methods. The above-described specific implementation methods are merely illustrative and not restrictive. Under the principle of the present disclosure, ordinary people skilled in the art can also make various improvements and modifications without departing from the objectives of the present disclosure and the scope of the claims, all of which belong to the scope of the present disclosure.

1. A vacuuming system for vacuuming multiple process chambers of a semiconductor process device, comprising:
multiple first vacuum pumping components; and
a second vacuum pumping component;
wherein:
the multiple process chambers are divided into multiple process chamber groups; each process chamber group includes multiple process chambers;
the multiple first vacuum pumping components are connected to the multiple process chamber groups in a one-to-one correspondence;
each first vacuum pumping component includes a first vacuum pump and multiple first vacuum pumping pipelines;
outlet ends of the multiple first vacuum pumping pipelines in each first vacuum pumping component are connected to the first vacuum pump;
inlet ends of the multiple first vacuum pumping pipelines in each first vacuum pumping component are respectively connected one-to-one with the multiple process chambers in each process chamber group;
the second vacuum pumping component includes a second vacuum pump and a second vacuum pumping pipeline;
an outlet end of the second vacuum pumping pipeline is connected to the second vacuum pump; and
an inlet end of the second vacuum pumping pipeline is connected to all the process chambers respectively.

2. The vacuuming system according to claim 1, wherein:
each first vacuum pumping pipeline includes a main pipeline, a control valve, and a first switch valve;
the main pipeline is used to connect the first vacuum pump and a corresponding process chamber;
the control valve and the first switch valve are both arranged in the main pipeline; and
the control valve is used to control a flow rate of gas in the main pipeline.

3. The vacuuming system according to claim 2, wherein:
each first vacuum pumping pipeline further includes a bypass pipeline;
a connection between an inlet end of the bypass pipeline and the main pipeline is located upstream of the first switch valve and the control valve;
a connection between an outlet end of the bypass pipeline and the main pipeline is located downstream of the first switch valve and the control valve;
a nominal diameter of the bypass pipeline is smaller than a nominal diameter of the main pipeline; and
the bypass pipeline includes a second switch valve.

4. The vacuuming system according to claim 3, wherein:
each first vacuum pumping pipeline further includes a regulating valve; and
the regulating valve is arranged in the bypass pipeline to adjust a flow conductance of the bypass pipeline.

5. The vacuuming system according to claim 3, wherein:
each first vacuum pumping pipeline further includes a pressure sensor;
the pressure sensor is connected to the main pipeline, and is used to detect a vacuum pressure in the main pipeline; and
the connection of the pressure sensor is located upstream of the connection between the inlet end of the bypass pipeline and the main pipeline.

6. The vacuuming system according to claim 5, wherein:
each first vacuum pumping pipeline further includes a pressure switch;
the pressure switch is connected to the main pipeline, and is used to detect a gas pressure in the main pipeline; and
the connection of the pressure switch is located upstream of the connection between the inlet end of the bypass pipeline and the main pipeline.

7. The vacuuming system according to claim 6, wherein:
each first vacuum pumping pipeline further includes a pressure relief pipeline, a third switch valve, and a one-way valve;
one end of the pressure relief pipeline is connected to the main pipeline, and the connection is located between the inlet end of the bypass pipeline and the connection between the main pipeline and the pressure switch; and
the third switch valve and the one-way valve are both arranged in the pressure relief pipeline, and the one-way valve is located downstream of the third switch valve.

8. The vacuuming system according to claim 2, wherein:
the control valve is a butterfly valve;
the control valve includes a valve body and a valve plate;
the valve body includes a through cavity, and the valve plate is rotatably arranged in the through cavity;
when the valve plate is perpendicular to a rotation axis of the through cavity, a preset gap is formed between an edge of the valve plate and an inner wall of the through cavity.

9. The vacuuming system according to claim 1, wherein:
the second vacuum pumping pipeline includes a common pipeline, multiple branch pipelines, and multiple fourth switch valves;
inlet ends of the multiple branch pipelines are connected to all the process chambers one by one, and outlet ends of the multiple branch pipelines are connected to the common pipeline;
the common pipeline is connected to the second vacuum pump; and
the multiple fourth switch valves are arranged one by one in the multiple branch pipelines.

10. A semiconductor process device, comprising a vacuuming system for vacuuming multiple process chambers of a semiconductor process device, wherein the vacuuming system comprises:
multiple first vacuum pumping components; and
a second vacuum pumping component;
wherein:
the multiple process chambers are divided into multiple process chamber groups; each process chamber group includes multiple process chambers;
the multiple first vacuum pumping components are connected to the multiple process chamber groups in a one-to-one correspondence;
each first vacuum pumping component includes a first vacuum pump and multiple first vacuum pumping pipelines;
outlet ends of the multiple first vacuum pumping pipelines in each first vacuum pumping component are connected to the first vacuum pump;
inlet ends of the multiple first vacuum pumping pipelines in each first vacuum pumping component are respectively connected one-to-one with the multiple process chambers in each process chamber group;
the second vacuum pumping component includes a second vacuum pump and a second vacuum pumping pipeline;
an outlet end of the second vacuum pumping pipeline is connected to the second vacuum pump; and
an inlet end of the second vacuum pumping pipeline is connected to all the process chambers respectively.

11. A method for vacuuming a semiconductor process device, comprising:
in response to a process chamber in a process chamber group undergoing a process, opening multiple first vacuum pipelines in a corresponding vacuum pumping component to use a first vacuum pump to vacuum multiple process chambers connected to the multiple first vacuum pipelines one by one; and
in response to a process chamber in the process chamber group having an abnormal alarm during the process, and other process chambers in the process chamber group processing normally, closing the first vacuum pipeline connected to the process chamber with the abnormal alarm, and opening a second vacuum pipeline to use a second vacuum pump to vacuum the process chamber with the abnormal alarm.

12. The semiconductor process device according to claim 10, wherein:
each first vacuum pumping pipeline includes a main pipeline, a control valve, and a first switch valve;
the main pipeline is used to connect the first vacuum pump and a corresponding process chamber;
the control valve and the first switch valve are both arranged in the main pipeline; and
the control valve is used to control a flow rate of gas in the main pipeline.

13. The semiconductor process device according to claim 12, wherein:
each first vacuum pumping pipeline further includes a bypass pipeline;
a connection between an inlet end of the bypass pipeline and the main pipeline is located upstream of the first switch valve and the control valve;
a connection between an outlet end of the bypass pipeline and the main pipeline is located downstream of the first switch valve and the control valve;
a nominal diameter of the bypass pipeline is smaller than a nominal diameter of the main pipeline; and
the bypass pipeline includes a second switch valve.

14. The semiconductor process device according to claim 13, wherein:
each first vacuum pumping pipeline further includes a regulating valve; and
the regulating valve is arranged in the bypass pipeline to adjust a flow conductance of the bypass pipeline

15. The semiconductor process device according to claim 13, wherein:
each first vacuum pumping pipeline further includes a pressure sensor;
the pressure sensor is connected to the main pipeline, and is used to detect a vacuum pressure in the main pipeline; and
the connection of the pressure sensor is located upstream of the connection between the inlet end of the bypass pipeline and the main pipeline.

16. The semiconductor process device according to claim 15, wherein:
each first vacuum pumping pipeline further includes a pressure switch;
the pressure switch is connected to the main pipeline, and is used to detect a gas pressure in the main pipeline; and
the connection of the pressure switch is located upstream of the connection between the inlet end of the bypass pipeline and the main pipeline.

17. The semiconductor process device according to claim 16, wherein:
each first vacuum pumping pipeline further includes a pressure relief pipeline, a third switch valve, and a one-way valve;
one end of the pressure relief pipeline is connected to the main pipeline, and the connection is located between the inlet end of the bypass pipeline and the connection between the main pipeline and the pressure switch; and
the third switch valve and the one-way valve are both arranged in the pressure relief pipeline, and the one-way valve is located downstream of the third switch valve.

18. The semiconductor process device according to claim 12, wherein:
the control valve is a butterfly valve;
the control valve includes a valve body and a valve plate;
the valve body includes a through cavity, and the valve plate is rotatably arranged in the through cavity;
when the valve plate is perpendicular to a rotation axis of the through cavity, a preset gap is formed between an edge of the valve plate and an inner wall of the through cavity.

19. The semiconductor process device according to claim 10, wherein:
the second vacuum pumping pipeline includes a common pipeline, multiple branch pipelines, and multiple fourth switch valves;
inlet ends of the multiple branch pipelines are connected to all the process chambers one by one, and outlet ends of the multiple branch pipelines are connected to the common pipeline;
the common pipeline is connected to the second vacuum pump; and
the multiple fourth switch valves are arranged one by one in the multiple branch pipelines.
